(19) United States
(12) Patent Application Publication
(10) Pub. No.: US 2026/0329139 A1
(43) Pub. Date: Oct. 22, 2026

(54) ELECTRO-OPTICAL DEVICE AND SPATIAL LIGHT MODULATOR

(71) Applicant: SONY SEMICONDUCTOR SOLUTIONS CORPORATION, KANAGAWA (JP)

(72) Inventor: YASUHIRO WATANABE, KANAGAWA (JP)

(21) Appl. No.: 19/486,399

(22) PCT Filed: May 8, 2024
(86) PCT No.: PCT/JP2024/017166

§ 371 Date: Nov. 21, 2025

(30) Foreign Application Priority Data
Jun. 9, 2023 (JP) 2023-095847

(51) Int. Cl. G02F 1/1368; G09G 3/36

(52) U.S. Cl. CPC G02F 1/1368; G09G 3/3648; G09G 2300/0426

(57) ABSTRACT

To provide an electro-optical device capable of suppressing an increase in size. An electro-optical device according to the present disclosure includes a liquid crystal element, a plurality of electronic components, a first semiconductor layer, and a second semiconductor layer. The liquid crystal element is driven on the basis of a data signal indicating a degree of light modulation. The plurality of electronic components is related to the driving of the liquid crystal element based on the data signal. A liquid crystal element and a subset of the plurality of electronic components are disposed in the first semiconductor layer. The second semiconductor layer is stacked on the first semiconductor layer, and remaining components of the plurality of electronic components are disposed.

### TECHNICAL FIELD

The present disclosure relates to an electro-optical device and a spatial light modulator.

### BACKGROUND ART

Electro-optical devices that modulate light on the basis of an input electrical signal are expected to be widely applied to liquid crystal display devices, stereoscopic displays, laser processing devices, and the like. An electro-optical device has a panel structure in which a liquid crystal layer is sandwiched between electrodes, and can change a phase, amplitude, transmittance, and the like of incident light by controlling a voltage applied to the liquid crystal layer. For this voltage control, the electro-optical device includes a pixel circuit.

The pixel circuit includes a large number of circuit elements including transistors such as metal-oxide-semiconductor field-effect transistors (MOSFETs) as electronic components related to driving of liquid crystal elements. In addition, each circuit element may be formed in an oxide semiconductor layer including a crystalline oxide such as zinc, tin, or indium. In this case, it is possible to form a transistor having a high voltage resistance and a low leakage current as compared with a MOSFET.

### CITATION LIST

### Patent Document

Patent Document 1: Japanese Patent Application Laid-Open No. 2013-257933

### SUMMARY OF THE INVENTION

### Problems to be Solved by the Invention

As described above, the pixel circuit includes a large number of electronic components. Therefore, when all the electronic components are disposed in one semiconductor layer, circuit area increases. As a result, the electro-optical device including the pixel circuit is increased in size.

Therefore, the present disclosure provides an electro-optical device and a spatial light modulator capable of suppressing an increase in size.

### Solutions to Problems

An electro-optical device according to the present disclosure includes a liquid crystal element driven on the basis of a data signal indicating a degree of light modulation, a plurality of electronic components related to the driving of the liquid crystal element based on the data signal, a first semiconductor layer in which the liquid crystal element and a subset of the plurality of electronic components are disposed, and a second semiconductor layer that is stacked on the first semiconductor layer and in which remaining components of the plurality of electronic components are disposed.

The first semiconductor layer may be an oxide semiconductor layer, and
the second semiconductor layer may be a silicon semiconductor layer.

The plurality of electronic components may include:
a sampling transistor that samples the data signal;
a buffer circuit that amplifies the data signal sampled by the sampling transistor; and
a transfer transistor that transfers the data signal amplified by the buffer circuit to the liquid crystal element.

The buffer circuit may be disposed in the first semiconductor layer, and
the sampling transistor and the transfer transistor may be disposed in the second semiconductor layer.

The sampling transistor and the transfer transistor may be CMOS transistors.

The buffer circuit and the transfer transistor may be disposed in the first semiconductor layer, and
the sampling transistor may be disposed in the second semiconductor layer.

The sampling transistor may be a CMOS transistor.

The sampling transistor and the transfer transistor may be disposed in the first semiconductor layer, and the buffer circuit may be disposed in the second semiconductor layer.

The buffer circuit may be a source follower circuit.

The buffer circuit may be a voltage follower circuit.

The plurality of electronic components may include two sampling transistors that sample the data signal and two transfer transistors that transfer the data signal sampled by the sampling transistors to the liquid crystal element,
the two transfer transistors may be disposed in the first semiconductor layer, and
the two sampling transistors may be disposed in the second semiconductor layer.

The two sampling transistors may be CMOS transistors.

The plurality of electronic components may include a signal generation circuit that generates the data signal, a buffer circuit that amplifies the data signal generated by the signal generation circuit, and a transfer transistor that transfers the data signal amplified by the buffer circuit to the liquid crystal element,
a part of the signal generation circuit, the buffer circuit, and the transfer transistor may be disposed in the first semiconductor layer, and
a remaining part of the signal generation circuit may be disposed in the second semiconductor layer.

The signal generation circuit may include a comparison circuit that compares a digital signal indicating a gradation value of the liquid crystal element with a reference signal, an AND circuit that performs an AND operation on a result of the comparison by the comparison circuit, a level shift circuit that shifts a level of a voltage of a digital signal indicating a result of the operation by the AND circuit, and a DAC transistor that performs analog conversion on the digital signal and that outputs the data signal,
the DAC transistor may be disposed in the first semiconductor layer, and
the comparison circuit, the AND circuit, and the level shift circuit may be disposed in the second semiconductor layer.

A spatial light modulator according to the present disclosure includes an electro-optical device. The electro-optical device includes:
a liquid crystal element driven on the basis of a data signal indicating a degree of light modulation;
a plurality of electronic components related to the driving of the liquid crystal element based on the data signal;
a first semiconductor layer in which the liquid crystal element and a subset of the plurality of electronic components are disposed; and
a second semiconductor layer that is stacked on the first semiconductor layer and in which remaining components of the plurality of electronic components are disposed.

### BRIEF DESCRIPTION OF DRAWINGS

FIG. 1 is a block diagram schematically illustrating an electro-optical device according to a first embodiment.

FIG. 2 is a diagram illustrating configuration of a pixel circuit according to a comparative example.

FIG. 3 is a diagram illustrating configuration of a pixel circuit according to the first embodiment.

FIG. 4 is a diagram illustrating configuration of a pixel circuit according to a second embodiment.

FIG. 5 is a diagram illustrating configuration of a pixel circuit according to a third embodiment.

FIG. 6 is a diagram illustrating configuration of a pixel circuit according to a fourth embodiment.

FIG. 7 is a diagram illustrating configuration of a pixel circuit according to a fifth embodiment.

FIG. 8 is a diagram illustrating configuration of a pixel circuit according to a sixth embodiment.

FIG. 9 is a diagram illustrating an example in which the electro-optical device is applied to a laser processing device.

FIG. 10 is a diagram illustrating an example in which the electro-optical device is applied to an optical computing device 109.

FIG. 11 is a diagram illustrating an example of external appearance of a head mounted display.

FIG. 12 is a diagram illustrating an example of external appearance of another head mounted display.

FIG. 13A is a front view of a digital still camera.

FIG. 13B is a rear view of the digital still camera.

FIG. 14 is a diagram illustrating an example of external appearance of a television apparatus.

FIG. 15 is a diagram illustrating an example of external appearance of a smartphone.

FIG. 16A is a diagram illustrating an example of an inside of a vehicle as viewed from a rear portion of a vehicle.

FIG. 16B is a diagram illustrating an example of the inside of the vehicle as viewed from a left rear portion of the vehicle.

FIG. 17 is a diagram illustrating an optical configuration example of a liquid crystal projector.

### MODE FOR CARRYING OUT THE INVENTION

Embodiments of the present disclosure will be described hereinafter with reference to the drawings. The drawings are used for description, and a shape and size of configuration of each of components of an actual device, a ratio of size of each component with respect to another component, and the like are not necessarily as illustrated in the drawings. In addition, since the drawings are illustrated in a simplified manner, components necessary for implementation other than those illustrated in the drawings are appropriately provided. In addition, in the description of the present disclosure, discharge of liquid crystal elements or capacitive elements is not particularly described, but a structure for discharging at least the liquid crystal elements or the capacitive elements may be appropriately provided.

### First Embodiment

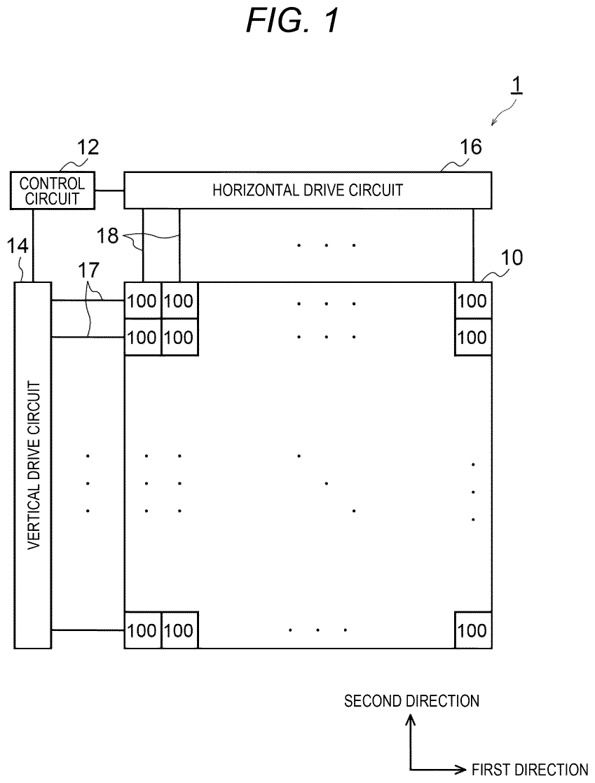

FIG. 1 is a block diagram schematically illustrating an electro-optical device according to a first embodiment. The electro-optical device 1 illustrated in FIG. 1 includes a pixel array 10, a control circuit 12, a vertical drive circuit 14, a horizontal drive circuit 16, first signal lines 17, and second signal lines 18.

The pixel array 10 includes a plurality of pixel circuits 100 arranged in an array in a first direction and a second direction intersecting the first direction. Each pixel circuit 100 includes a display element. Using each pixel circuit 100, the electro-optical device 1 displays a direct view image or a projection image, or displays a Computer-Generated Hologram (CGH) for light modulation. The first direction and the second direction represent a pixel column direction and a pixel row direction, respectively, as a non-limiting example.

The control circuit 12 is a circuit that controls display of an image to be displayed on the pixel array 10 or display for light modulation. The control circuit 12 controls each pixel circuit 100 of the pixel array 10 by transmitting control signals to the vertical drive circuit 14 and the horizontal drive circuit 16.

The vertical drive circuit 14 transmits a signal for controlling which pixel row the pixel circuits 100 belonging to are to be driven in the pixel array 10. Pixel circuits 100 belonging to the same pixel row are connected to the same first signal line 17. The vertical drive circuit 14 outputs drive signals for controlling driving of the pixel circuits 100 belonging to the respective pixel rows via the first signal lines 17.

The horizontal drive circuit 16 transmits, for each pixel column, signals indicating display intensity or a degree of light modulation to the pixel circuits 100 driven and controlled by the vertical drive circuit 14. Pixel circuits 100 belonging to the same pixel column are connected to the same second signal line 18. The horizontal drive circuit 16 outputs signals (reference signals) for controlling intensity and the like of the pixel circuits 100 belonging to the respective pixel columns via the second signal lines 18.

As an example, the horizontal drive circuit 16 starts outputting ramp signals at a timing controlled by the control circuit 12 for each pixel column. Each pixel circuit 100 reads a signal value of the ramp signal transmitted from the horizontal drive circuit 16 via the second signal line 18 at an appropriate timing, thereby driving the liquid crystal element with an appropriate intensity or an appropriate degree of light modulation.

As described above, by appropriately driving each pixel circuit 100, the electro-optical device 1 can display an appropriate image or set appropriate degrees of light modulation in the pixel array 10.

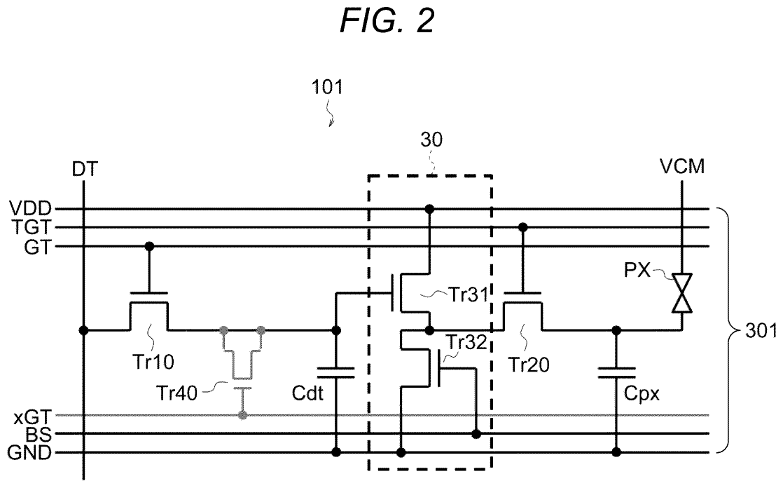

Here, configuration of a pixel circuit according to a comparative example compared with the first embodiment will be described with reference to FIG. 2.

FIG. 2 is a diagram illustrating configuration of the pixel circuit according to the comparative example. A pixel circuit 101 illustrated in FIG. 2 includes a sampling transistor Tr10, a transfer transistor Tr20, a buffer circuit 30, a liquid crystal element PX, a data sampling capacitive element Cdt, a data transfer capacitive element Cpx, and a dummy transistor Tr40.

The pixel circuit 101 is formed in a first semiconductor layer 301. The first semiconductor layer 301 is an oxide semiconductor layer. Furthermore, each transistor provided in the pixel circuit 101 is an N-type transistor.

The sampling transistor Tr10 performs sampling processing on a data signal for determining light modulation intensity of the liquid crystal element PX. A gate of the sampling transistor Tr10 is connected to a sampling gate signal line GT. The sampling gate signal line GT is connected to the above-described first signal line 17 (see FIG. 1). A drain of the sampling transistor Tr10 is connected to a data signal line DT. The data signal line DT is connected to the above-described second signal line 18 (see FIG. 1). A source of the sampling transistor Tr10 is connected to one end of the data sampling capacitive element Cdt and an input terminal of the buffer circuit 30.

The data sampling capacitive element Cdt holds a voltage value of the data signal sampled by the sampling transistor Tr10. Another end of the data sampling capacitive element Cdt is connected to a ground line GND.

The buffer circuit 30 amplifies the voltage value of the data signal held in the data sampling capacitive element Cdt.

The buffer circuit 30 includes a first buffer transistor Tr31 and a second buffer transistor Tr32 connected in series to the first buffer transistor Tr31.

A gate of the first buffer transistor Tr31 corresponds to an input terminal of the buffer circuit 30 and is connected to one end of the data sampling capacitive element Cdt. A drain of the first buffer transistor Tr31 is connected to a power supply line VDD. A source of the first buffer transistor Tr31 is connected to a drain of the second buffer transistor Tr32. The source of the first buffer transistor Tr31 and the drain of the second buffer transistor Tr32 correspond to an output terminal of the buffer circuit 30.

A gate of the second buffer transistor Tr32 is connected to a buffer gate signal line BS. The buffer gate signal line BS is connected to the first signal line 17 different from the sampling gate signal line GT. A source of the second buffer transistor Tr32 is connected to the ground line GND. The second buffer transistor Tr32 functions as a current source transistor that outputs a constant current according to the gate voltage.

The transfer transistor Tr20 transfers the data signal amplified by the buffer circuit 30 to the liquid crystal element PX. A gate of the transfer transistor Tr20 is connected to a transfer gate signal line TGT. The transfer gate signal line TGT is connected to the first signal line 17 different from the sampling gate signal line GT and the buffer gate signal line BS. A source of the transfer transistor Tr20 is connected to one end of the data transfer capacitive element Cpx and the liquid crystal element PX.

The data transfer capacitive element Cpx holds the voltage value of the data signal transferred by the transfer transistor Tr20. Another end of the data transfer capacitive element Cpx is connected to the ground line GND.

The liquid crystal element PX is driven on the basis of the data signal held in the data transfer capacitive element Cpx. In the liquid crystal element PX, an angle of liquid crystal molecules is set according to the voltage value of the data signal. A degree of light modulation is set for each pixel circuit 101 on the basis of this angle. One end of the liquid crystal element PX is connected to one end of the data transfer capacitive element Cpx, and another end is connected to a reference voltage line VCM.

The dummy transistor Tr40 cancels switching noise of the sampling transistor Tr10. A gate of the dummy transistor Tr40 is connected to an inverted sampling gate signal line xGT. The inverted sampling gate signal line xGT is connected to the first signal line 17 different from the sampling gate signal line GT, the transfer gate signal line TGT, and the buffer gate signal line BS. A drain and a source of the dummy transistor Tr40 are commonly connected to the source of the sampling transistor Tr10. In the present embodiment, channel length and channel width of the dummy transistor Tr40 are about half of those of the sampling transistor Tr10.

The pixel circuit 101 configured as described above has a concern about technical problems such as switching noise of the sampling transistor Tr10 or the transfer transistor Tr20 and insufficient operation speed. As a countermeasure against these technical problems, installation of the dummy transistor Tr40 for canceling the switching noise is effective. In addition, it is also effective to increase capacitance values of the data sampling capacitive element Cdt and the data transfer capacitive element Cpx in order to absorb the switching noise. Furthermore, it is also effective to increase the size of the sampling transistor Tr10 or the transfer transistor Tr20 in order to lower on-resistance. These countermeasures, however, lead to an increase in planar area of the pixel circuit 101. Therefore, an increase in size of the device cannot be avoided.

Therefore, in the pixel circuit 100 according to the first embodiment, transistor characteristics are improved while suppressing an increase in the size of the device. Circuit configuration of the pixel circuit 100 will be described in detail hereinafter.

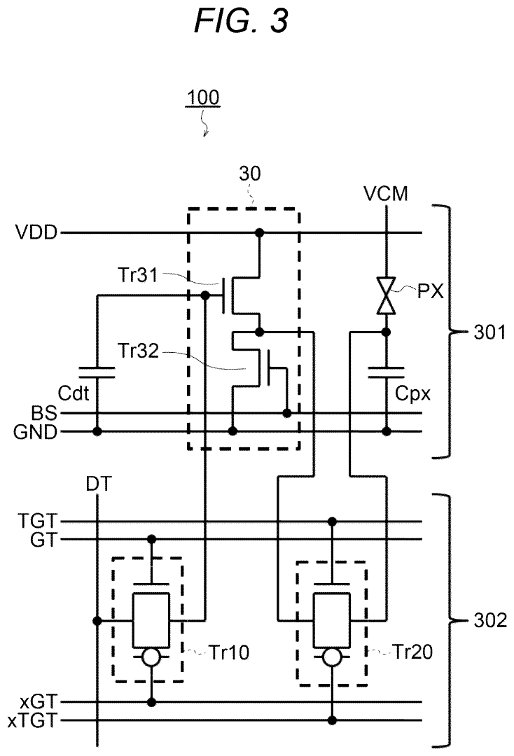

FIG. 3 is a diagram illustrating circuit configuration of the pixel circuit 100 according to the first embodiment. Circuit elements similar to those of the pixel circuit 101 according to the above-described comparative example will be denoted by the same reference numerals, and detailed description thereof is omitted.

The pixel circuit 100 according to the present embodiment is formed in the first semiconductor layer 301 and a second semiconductor layer 302. The second semiconductor layer 302 is stacked under the first semiconductor layer 301. The first semiconductor layer 301 and the second semiconductor layer 302 have a monolithic structure, where the first semiconductor layer 301 and the second semiconductor layer 302 are integrally formed. The first semiconductor layer 301 is an oxide semiconductor layer as in the comparative example. On the other hand, the second semiconductor layer 302 is a silicon semiconductor layer.

In the first semiconductor layer 301, the buffer circuit 30, the liquid crystal element PX, the data sampling capacitive element Cdt, and the data transfer capacitive element Cpx are disposed. Therefore, the power supply line VDD, the buffer gate signal line BS, and the ground line GND are also disposed in the first semiconductor layer 301. In the present embodiment, each of the buffer circuit 30, the data sampling capacitive element Cdt, and the data transfer capacitive element Cpx corresponds to an electronic component related to the driving of the liquid crystal element PX.

On the other hand, the second semiconductor layer 302 is provided with the sampling transistor Tr10 and the transfer transistor Tr20. Each of the sampling transistor Tr10 and the transfer transistor Tr20 is a Complementary Metal-Oxide-Semiconductor (CMOS) transistor in which a P-type transistor and an N-type transistor are complementarily connected. The CMOS transistor also corresponds to an electronic component related to the driving of the liquid crystal element PX.

A gate of the N-type transistor of the sampling transistor Tr10 is connected to the sampling gate signal line GT. A gate of the P-type transistor of the sampling transistor Tr10 is connected to the inverted sampling gate signal line xGT. Note that the pixel circuit 100 is not provided with the dummy transistor Tr40. The sampling gate signal line GT and the inverted sampling gate signal line xGT are also disposed in the second semiconductor layer 302.

A gate of the N-type transistor of the transfer transistor Tr20 is connected to the transfer gate signal line TGT. A gate of the P-type transistor of the transfer transistor Tr20 is connected to the inverted transfer gate signal line xTGT. The transfer gate signal line TGT and the inverted transfer gate signal line xTGT are also disposed in the second semiconductor layer 302.

In the pixel circuit 100 configured as described above, first, when the sampling transistor Tr10 is turned on on the basis of a gate signal input through the sampling gate signal line GT and the inverted sampling gate signal line xGT, a data signal is input to the sampling transistor Tr10 through the data signal line DT formed in the second semiconductor layer 302. A voltage value of the data signal is transmitted from the second semiconductor layer 302 to the first semiconductor layer 301 and held in the data sampling capacitive element Cdt.

Subsequently, the data signal held in the data sampling capacitive element Cdt is amplified by the buffer circuit 30 in the first semiconductor layer 301 and transmitted from the first semiconductor layer 301 to the second semiconductor layer 302.

Subsequently, when the transfer transistor Tr20 is turned on on the basis of a gate signal input through the transfer gate signal line TGT and the inverted transfer gate signal line xTGT, the data signal amplified in the buffer circuit 30 is transmitted from the second semiconductor layer 302 to the first semiconductor layer 301 via the transfer transistor Tr20 and transferred to the liquid crystal element PX. At this time, a voltage value of the data signal is held in the data transfer capacitive element Cpx in the first semiconductor layer 301.

Lastly, the liquid crystal element PX optically modulates incident light on the basis of the data signal. As a result, a two-dimensional image or a stereoscopic image based on the data signal is output from the first semiconductor layer 301.

In the pixel circuit 101 according to the above-described comparative example, all the electronic components related to the driving of the liquid crystal element PX are disposed in the first semiconductor layer 301 as illustrated in FIG. 2. On the other hand, in the pixel circuit 100 according to the present embodiment, a plurality of electronic components is dispersedly disposed in the first semiconductor layer 301 and the second semiconductor layer 302. Since the second semiconductor layer 302 is stacked on the first semiconductor layer 301, the pixel circuit 100 according to the present embodiment has a vertical structure. Therefore, planar area of the pixel circuit 100 according to the present embodiment can be made smaller than the planar area of the pixel circuit 101 according to the comparative example. As a result, the pixel circuit can be miniaturized to reduce chip area. As a result, it is possible to suppress an increase in size of the electro-optical device 1.

In addition, in the present embodiment, the sampling transistor Tr10 and the transfer transistor Tr20 are provided in the second semiconductor layer 302, which is a silicon semiconductor layer. In the silicon semiconductor layer, electron mobility is higher than that of the first semiconductor layer 301, which is an oxide semiconductor layer. Therefore, the switching operation of the sampling transistor Tr10 and the transfer transistor Tr20 is speeded up. As a result, the sampling processing and the transfer processing of the data signal can be speeded up. Furthermore, in the present embodiment, since the sampling transistor Tr10 and the transfer transistor Tr20 are CMOS transistors, switching noise can be suppressed without disposing the dummy transistor Tr40. As a result, the switching operation is further speeded up.

Therefore, drive characteristic of the pixel circuit can be further improved.

### Second Embodiment

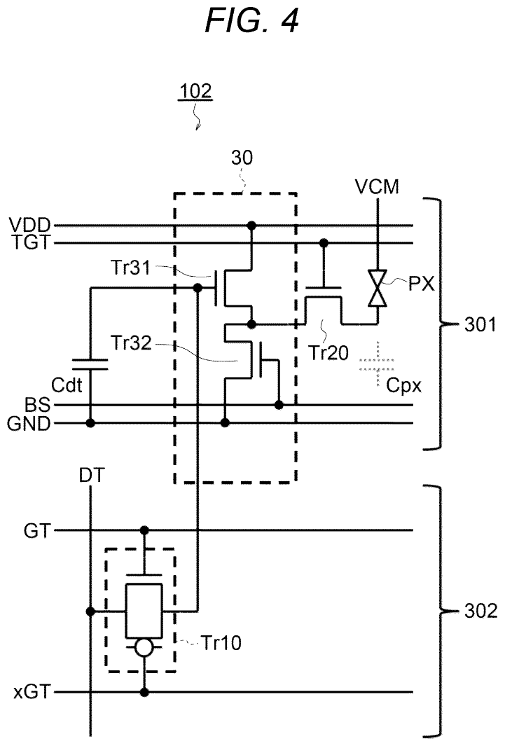

FIG. 4 is a diagram illustrating configuration of a pixel circuit according to a second embodiment. A pixel circuit 102 according to the present embodiment is also formed in the first semiconductor layer 301 and the second semiconductor layer 302 similarly to the first embodiment.

On the other hand, in the present embodiment, among the electronic components of the pixel circuit 102, only the sampling transistor Tr10 is disposed in the second semiconductor layer 302. Therefore, in the second semiconductor layer 302, the sampling gate signal line GT and the inverted sampling gate signal line xGT are also disposed in the second semiconductor layer 302.

Furthermore, in the pixel circuit 102 according to the present embodiment, the transfer transistor Tr20 is disposed as a single N-type transistor in the first semiconductor layer 301. Therefore, the inverted transfer gate signal line xTGT is unnecessary. Furthermore, the pixel circuit 102 is not provided with the data transfer capacitive element Cpx.

In the pixel circuit 102 configured as described above, first, when the sampling transistor Tr10 is turned on on the basis of a gate signal as in the first embodiment, a data signal is input to the sampling transistor Tr10 through the data signal line DT formed in the second semiconductor layer 302. A voltage value of the data signal is transmitted from the second semiconductor layer 302 to the first semiconductor layer 301 and held in the data sampling capacitive element Cdt.

Subsequently, the data signal held in the data sampling capacitive element Cdt is amplified by the buffer circuit 30 in the first semiconductor layer 301.

Subsequently, when the transfer transistor Tr20 is turned on on the basis of a gate signal input through the transfer gate signal line TGT, the data signal amplified in the buffer circuit 30 is transferred to the liquid crystal element PX in the first semiconductor layer 301 via the transfer transistor Tr20.

Lastly, the liquid crystal element PX optically modulates incident light on the basis of the data signal. As a result, a two-dimensional image or a stereoscopic image based on the data signal is output from the first semiconductor layer 301.

There is a case where the transfer transistor Tr20 is not required to speed up the switching operation unlike the sampling transistor Tr10. In this case, the switching noise of the transfer transistor Tr20 can be suppressed even without the data transfer capacitive element Cpx. In addition, when a transistor is formed in the first semiconductor layer 301, which is an oxide semiconductor layer, excellent electrical characteristics such as a low leakage current and a high voltage resistance can be obtained. Therefore, it is not necessary to hold the voltage value of the data signal transferred to the liquid crystal element PX in the data transfer capacitive element Cpx.

Therefore, in the present embodiment, the sampling transistor Tr10 in which the switching noise needs to be suppressed is formed in the second semiconductor layer 302. On the other hand, in order to obtain excellent electrical characteristics as described above, the transfer transistor Tr20 is formed in the first semiconductor layer 301.

According to the present embodiment described above, the sampling transistor Tr10, which is one of the electronic components related to the driving of the liquid crystal element PX, is disposed in the second semiconductor layer 302. Therefore, planar area of the pixel circuit 102 according to the present embodiment can be made smaller than the planar area of the pixel circuit 101 according to the comparative example. As a result, the pixel circuit can be miniaturized to reduce chip area. As a result, it is possible to suppress an increase in size of the electro-optical device 1.

Furthermore, in the present embodiment, the data transfer capacitive element Cpx is not provided. Therefore, the planar area of the pixel circuit 102 can be further reduced.

### Third Embodiment

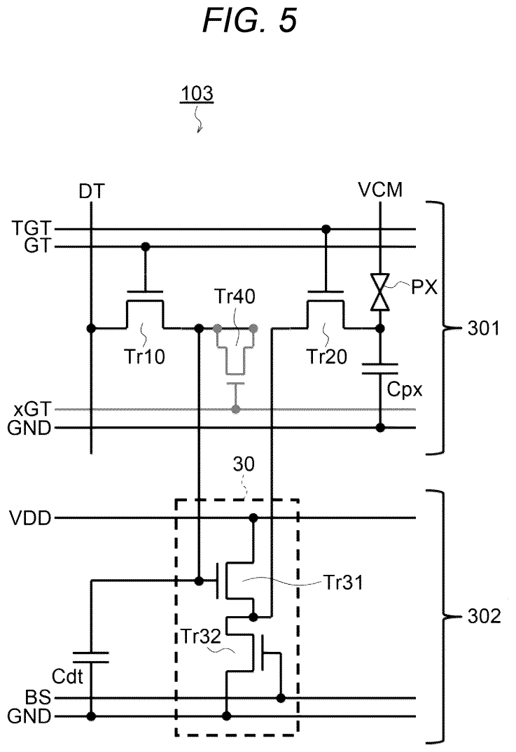

FIG. 5 is a diagram illustrating configuration of a pixel circuit according to a third embodiment. A pixel circuit 103 according to the present embodiment is also formed in the first semiconductor layer 301 and the second semiconductor layer 302 similarly to the first embodiment.

On the other hand, in the present embodiment, among circuit elements of the pixel circuit 103, the data sampling capacitive element Cdt and the buffer circuit 30 are provided in the second semiconductor layer 302. Therefore, the power supply line VDD, the buffer gate signal line BS, and the ground line GND are also disposed in the second semiconductor layer 302. Furthermore, the first semiconductor layer 301 is provided with the dummy transistor Tr40.

In the pixel circuit 103 configured as described above, first, when the sampling transistor Tr10 is turned on on the basis of a gate signal as in the first embodiment, a data signal is input to the sampling transistor Tr10 through the data signal line DT formed in the first semiconductor layer 301. A voltage value of the data signal is transmitted from the first semiconductor layer 301 to the second semiconductor layer 302 and held in the data sampling capacitive element Cdt. At this time, the switching noise generated in the sampling transistor Tr10 is suppressed by the dummy transistor Tr40 provided in the first semiconductor layer 301.

Subsequently, the data signal held in the data sampling capacitive element Cdt is amplified by the buffer circuit 30 in the second semiconductor layer 302 and transmitted from the second semiconductor layer 302 to the first semiconductor layer 301.

Subsequently, when the transfer transistor Tr20 is turned on on the basis of a gate signal input through the transfer gate signal line TGT, the data signal amplified in the buffer circuit 30 is transferred to the liquid crystal element PX in the first semiconductor layer 301 via the transfer transistor Tr20. At this time, a voltage value of the data signal is held in the data transfer capacitive element Cpx in the first semiconductor layer 301.

Lastly, the liquid crystal element PX optically modulates incident light on the basis of the data signal. As a result, a two-dimensional image or a stereoscopic image based on the data signal is output from the first semiconductor layer 301.

According to the present embodiment described above, the data sampling capacitive element Cdt, the buffer circuit 30, and the sampling transistor Tr10, which are electronic components related to the driving of the liquid crystal element PX, are disposed in the second semiconductor layer 302. Therefore, planar area of the pixel circuit 103 according to the present embodiment can be made smaller than the planar area of the pixel circuit 101 according to the comparative example. As a result, the pixel circuit can be miniaturized to reduce chip area. As a result, it is possible to suppress an increase in size of the device.

### Fourth Embodiment

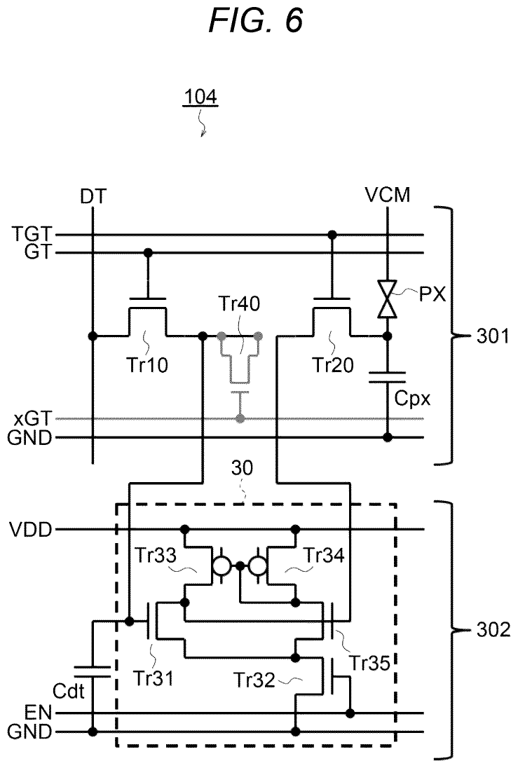

FIG. 6 is a diagram illustrating configuration of a pixel circuit according to a fourth embodiment. In a pixel circuit 104 according to the present embodiment, similarly to the pixel circuit 103 according to the third embodiment described above, the data sampling capacitive element Cdt and the buffer circuit 30 are provided in the second semiconductor layer 302. On the other hand, in the present embodiment, the configuration of the buffer circuit 30 is different from that of the third embodiment.

The buffer circuit 30 according to the third embodiment is a source follower circuit in which the source of the first buffer transistor Tr31 is connected to the ground line GND via the second buffer transistor Tr32. On the other hand, the buffer circuit 30 according to the present embodiment is a voltage follower circuit.

Specifically, as illustrated in FIG. 6, the buffer circuit 30 according to the present embodiment further includes a third buffer transistor Tr33, a fourth buffer transistor Tr34, and a fifth buffer transistor Tr35 in addition to the first buffer transistor Tr31 and the second buffer transistor Tr32.

The third buffer transistor Tr33 and the fourth buffer transistor Tr34 are both P-type transistors and constitute a current mirror circuit. Gates of the third buffer transistor Tr33 and the fourth buffer transistor Tr34 are connected to each other. Sources of the third buffer transistor Tr33 and the fourth buffer transistor Tr34 are commonly connected to the power supply line VDD. A drain of the third buffer transistor Tr33 is connected to a drain of the first buffer transistor Tr31. The drain of the fourth buffer transistor Tr34 is connected to itself and the gate of the third buffer transistor Tr33.

The fifth buffer transistor Tr35 includes an N-type transistor. A gate of the fifth buffer transistor Tr35 corresponds to the output terminal of the buffer circuit 30, and is connected to the drain of the transfer transistor Tr20. A drain of the fifth buffer transistor Tr35 is connected to the gates of the third buffer transistor Tr33 and the fourth buffer transistor Tr34 and the drain of the fourth buffer transistor Tr34. A source of the fifth buffer transistor Tr35 is connected to the drain of the second buffer transistor Tr32.

In the pixel circuit 104 configured as described above, first, when the sampling transistor Tr10 is turned on on the basis of a gate signal as in the first embodiment, a data signal is input to the sampling transistor Tr10 through the data signal line DT formed in the first semiconductor layer 301. A voltage value of the data signal is transmitted from the first semiconductor layer 301 to the second semiconductor layer 302 and held in the data sampling capacitive element Cdt. At this time, the switching noise generated in the sampling transistor Tr10 is suppressed by the dummy transistor Tr40 provided in the first semiconductor layer 301.

Subsequently, the data signal held in the data sampling capacitive element Cdt is amplified by the buffer circuit 30 in the second semiconductor layer 302 and transmitted from the second semiconductor layer 302 to the first semiconductor layer 301. In the present embodiment, the buffer circuit 30 is a voltage follower circuit. Therefore, in the buffer circuit 30, the third buffer transistor Tr33 to the fifth buffer transistor Tr35 perform a feedback operation such that a gate voltage, in other words, an input voltage, of the first buffer transistor Tr31 and a gate voltage, in other words, a circumferential force voltage, of the fifth buffer transistor Tr35 match.

Subsequently, when the transfer transistor Tr20 is turned on on the basis of a gate signal input through the transfer gate signal line TGT, the data signal amplified in the buffer circuit 30 is transferred to the liquid crystal element PX in the first semiconductor layer 301 via the transfer transistor Tr20. At this time, a voltage value of the data signal is held in the data transfer capacitive element Cpx in the first semiconductor layer 301.

Lastly, the liquid crystal element PX optically modulates incident light on the basis of the data signal. As a result, a two-dimensional image or a stereoscopic image based on the data signal is output from the first semiconductor layer 301.

According to the present embodiment described above, the data sampling capacitive element Cdt, the buffer circuit 30, and the sampling transistor Tr10, which are electronic components related to the driving of the liquid crystal element PX, are disposed in the second semiconductor layer 302. Therefore, planar area of the pixel circuit 104 according to the present embodiment can be made smaller than the planar area of the pixel circuit 101 according to the comparative example. As a result, the pixel circuit can be miniaturized to reduce chip area. As a result, it is possible to suppress an increase in size of the device.

In addition, in the present embodiment, since the second semiconductor layer 302 is a silicon semiconductor layer, a P-type transistor can be formed. Therefore, the buffer circuit 30 can be a voltage follower circuit by forming the third buffer transistor Tr33 and the fourth buffer transistor Tr34. As a result, the buffer circuit 30 according to the present embodiment is less likely to be affected by fluctuations in electrical characteristics (for example, gate-source threshold voltages) of the first buffer transistor Tr31 and the second buffer transistor Tr32, as compared with the buffer circuit 30 according to the third embodiment including a source follower circuit. Therefore, gain and accuracy of an output signal of the buffer circuit 30 are improved.

### Fifth Embodiment

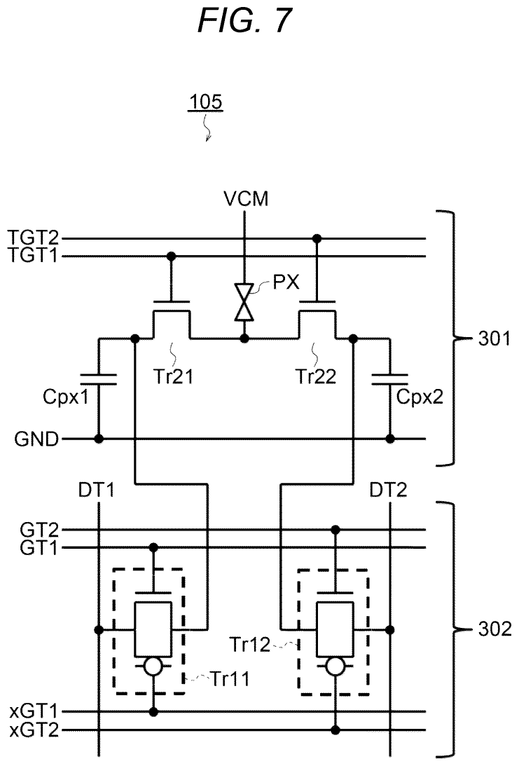

FIG. 7 is a diagram illustrating configuration of a pixel circuit according to a fifth embodiment. In the pixel circuit 105 according to the present embodiment, only a sampling transistor is disposed in the second semiconductor layer 302 as in the second embodiment. On the other hand, the number of sampling transistors and transfer transistors is different from that of the second embodiment. Specifically, the pixel circuit 105 includes a first sampling transistor Tr11 and a second sampling transistor Tr12, and includes a first transfer transistor Tr21 and a second transfer transistor Tr22. Furthermore, since the pixel circuit 105 according to the present embodiment is a so-called capacitance holding type, the data sampling capacitive element Cdt and the buffer circuit 30 are not provided.

The first sampling transistor Tr11 and the second sampling transistor Tr12 are disposed in the second semiconductor layer 302. The first sampling transistor Tr11 and the second sampling transistor Tr12 are both CMOS transistors.

A gate of an N-type transistor of the first sampling transistor Tr11 is connected to a first sampling gate signal line GT1. A gate of a P-type transistor of the first sampling transistor Tr11 is connected to a first inverted sampling gate signal line xGT1. A drain of the first sampling transistor Tr11 is connected to a first data signal line DT1. A source of the first sampling transistor Tr11 is connected to one end of a first data transfer capacitive element Cpx1.

A gate of an N-type transistor of the second sampling transistor Tr12 is connected to a second sampling gate signal line GT2. A gate of a P-type transistor of the second sampling transistor Tr12 is connected to a second inverted sampling gate signal line xGT2. A drain of the second sampling transistor Tr12 is connected to a second data signal line DT2. A source of the second sampling transistor Tr12 is connected to one end of a second data transfer capacitive element Cpx2.

The first transfer transistor Tr21 and the second transfer transistor Tr22 are disposed in the first semiconductor layer 301. The first transfer transistor Tr21 and the second transfer transistor Tr22 are both N-type transistors.

A gate of the first transfer transistor Tr21 is connected to a first transfer gate signal line TGT1. A drain of the first transfer transistor Tr21 is connected to one end of the first data transfer capacitive element Cpx1 and the source of the first sampling transistor Tr11. A source of the first transfer transistor Tr21 is connected to the liquid crystal element PX.

A gate of the second transfer transistor Tr22 is connected to a second transfer gate signal line TGT2. A drain of the second transfer transistor Tr22 is connected to one end of the second data transfer capacitive element Cpx2 and the source of the second sampling transistor Tr12. A source of the second transfer transistor Tr22 is connected to the liquid crystal element PX in common with the source of the first transfer transistor Tr21.

In the pixel circuit 104 configured as described above, first, when the first sampling transistor Tr11 is turned on on the basis of a gate signal input through the first sampling gate signal line GT1 formed in the second semiconductor layer 302, a first data signal is input to the first sampling transistor Tr11 through the first data signal line DT1 formed in the second semiconductor layer 302. A voltage value of the first data signal is transmitted from the second semiconductor layer 302 to the first semiconductor layer 301 and held in the first data transfer capacitive element Cpx1.

Subsequently, for example, in a first frame period, when the first transfer transistor Tr21 is turned on on the basis of a gate signal input through the first transfer gate signal line TGT1 formed in the first semiconductor layer 301, the first data signal held in the first data transfer capacitive element Cpx1 is transferred to the liquid crystal element PX via the first transfer transistor Tr21. At this time, when the second sampling transistor Tr12 is turned on on the basis of a gate signal input through the second sampling gate signal line GT2 formed in the second semiconductor layer 302, for example, a second data signal transferred to the liquid crystal element PX in a second frame period is input to the second sampling transistor Tr12 through the second data signal line DT2 formed in the second semiconductor layer 302. A voltage value of the second data signal is transmitted from the second semiconductor layer 302 to the first semiconductor layer 301 and held in the second data transfer capacitive element Cpx2.

Subsequently, for example, in the second frame period, when the second transfer transistor Tr22 is turned on on the basis of a gate signal input through the second transfer gate signal line TGT2 formed in the first semiconductor layer 301, the second data signal held in the second data transfer capacitive element Cpx2 is transferred to the liquid crystal element PX via the second transfer transistor Tr22. At this time, when the first sampling transistor Tr11 is turned on on the basis of a gate signal input through the first sampling gate signal line GT1 formed in the second semiconductor layer 302, for example, a new first data signal transferred to the liquid crystal element PX in a third frame period is input to the first sampling transistor Tr11 through the first data signal line DT1 formed in the second semiconductor layer 302. Thereafter, the above operation is repeated.

Lastly, the liquid crystal element PX optically modulates incident light on the basis of the first data signal and the second data signal. As a result, a two-dimensional image or a stereoscopic image based on the data signal is output from the first semiconductor layer 301.

According to the present embodiment described above, the first sampling transistor Tr11 and the second sampling transistor Tr12, which are electronic components related to the driving of the liquid crystal element PX, are disposed in the second semiconductor layer 302. Therefore, planar area of the pixel circuit 105 according to the present embodiment can be made smaller than planar area of the pixel circuit in which these sampling transistors are disposed in the first semiconductor layer 301. As a result, the pixel circuit can be miniaturized to reduce chip area. As a result, it is possible to suppress an increase in size of the device.

Furthermore, since the pixel circuit 105 according to the present embodiment does not require the data sampling capacitive element Cdt and the buffer circuit 30, the circuit area can be further reduced.

### Sixth Embodiment

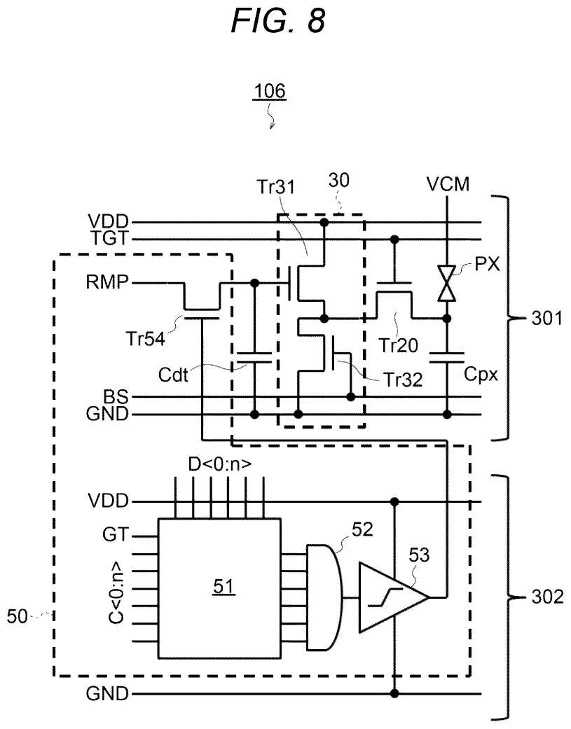

FIG. 8 is a diagram illustrating configuration of a pixel circuit according to a sixth embodiment. In a pixel circuit 106 according to the present embodiment, a signal generation circuit 50 that generates a data signal is provided. This eliminates the need for the sampling transistor Tr10 and the data signal line DT in the pixel circuit 106.

The signal generation circuit 50 is one of electronic components related to the driving of the liquid crystal element PX, and includes a comparison circuit 51, an AND circuit 52, a level shift circuit 53, and a Digital Analog Converter (DAC) transistor Tr54. The comparison circuit 51, the AND circuit 52, and the level shift circuit 53 are formed in the second semiconductor layer 302, and the DAC transistor Tr54 is formed in the first semiconductor layer 301.

The comparison circuit 51 compares a digital signal constructed with a predetermined number of bits indicating a gradation value of liquid crystal element PX with a reference signal. The gradation value is stored in, for example, a memory circuit (not illustrated). In addition, the reference signal is a signal based on a count value output from a counter (not illustrated) and counted up from a minimum value to a maximum value.

The AND circuit 52 performs a logical product (AND) operation on a result of the comparison by the comparison circuit 51. The level shift circuit 53 boosts a voltage value of a pulse signal indicating a result of the logical operation by the AND circuit 52 to a voltage value suitable for analog conversion in the DAC transistor Tr54.

The DAC transistor Tr54 includes an N-type transistor, and performs a switching operation on the basis of the pulse signal level-shifted by the level shift circuit 53. A ramp signal RMP indicating analog gradation is input from a peripheral circuit of the pixel or the like to a drain of the DAC transistor Tr54. A source of the DAC transistor Tr54 is connected to one end of the data sampling capacitive element Cdt.

In the pixel circuit 104 configured as described above, first, a pulse signal is generated by the comparison circuit 51, the AND circuit 52, and the level shift circuit 53.

Subsequently, the ramp signal RMP is input to the DAC transistor Tr54 at a timing when the DAC transistor Tr54 is turned on on the basis of the pulse signal. As a result, the signal generation circuit 50 converts the digital signal input to the comparison circuit 51 into an analog data signal using the ramp signal RMP. The data signal is held in the data sampling capacitive element Cdt in the first semiconductor layer 301.

Subsequently, the data signal held in the data sampling capacitive element Cdt is amplified by the buffer circuit 30 in the first semiconductor layer 301.

Subsequently, when the transfer transistor Tr20 is turned on on the basis of a gate signal input through the transfer gate signal line TGT, the data signal amplified in the buffer circuit 30 is transferred to the liquid crystal element PX in the first semiconductor layer 301 via the transfer transistor Tr20. At this time, a voltage value of the data signal is held in the data transfer capacitive element Cpx in the first semiconductor layer 301.

Lastly, the liquid crystal element PX optically modulates incident light on the basis of the data signal. As a result, a two-dimensional image or a stereoscopic image based on the data signal is output from the first semiconductor layer 301.

According to the present embodiment described above, pixel functions are integrated in the first semiconductor layer 301. In addition, a signal generation circuit 50 conventionally disposed around the pixel circuit 106 is dispersedly disposed in the first semiconductor layer 301 and the signal generation circuit 50. As a result, chip area on which the pixel circuit 106 is mounted can be reduced. As a result, it is possible to suppress an increase in size of the device.

In addition, in the present embodiment, the signal generation circuit 50 is formed in the second semiconductor layer 302 stacked on the first semiconductor layer 301.

Therefore, since the analog data signal line DT is unnecessary, data processing speed is improved. Therefore, the operation can be speeded up.

The pixel circuits described in the first to sixth embodiments described above can be applied to various spatial light modulators described below. Therefore, application examples of the electro-optical device will be described.

### First Application Example

For example, the electro-optical device can operate as a spatial light modulator that reflects light transmitted through the liquid crystal element PX and that outputs the light from a display surface by forming an appropriate reflection film on a side opposite to the display surface of the liquid crystal element PX. For example, the electro-optical device 1 can control the degree of phase modulation by the liquid crystal element PX in consideration of double pass due to reflection.

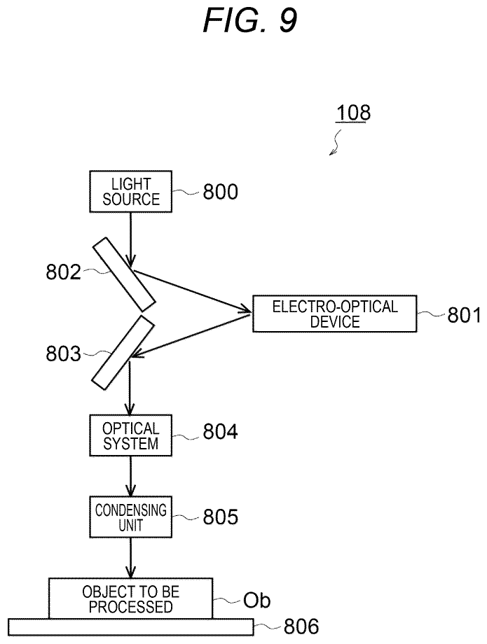

FIG. 9 is a diagram illustrating an example in which the electro-optical device is applied to a laser processing device. A laser processing device 108 illustrated in FIG. 9 includes a light source 800, an electro-optical device 801, a mirror 802, a mirror 803, an optical system 804, a condensing unit 805, and a support unit 806.

The light source 800 may be, for example, a solid laser, a liquid laser, a gas laser, or a semiconductor laser such as a Laser Diode (LD). The light source 800 emits laser light by, for example, a pulse transmission method. The laser light may be linearly polarized light.

The electro-optical device 801 includes any one of the pixel circuits described in the first to sixth embodiments. Furthermore, pixel circuits of the electro-optical device 801 may have a pixel pitch at which appropriate phase modulation can be performed in the laser processing device 108, for example, a pixel pitch of 3.6 um or less. The electro-optical device 801 appropriately phase-modulates laser light reflected by the mirror 802 and outputs the laser light to the mirror 803.

The mirror 802 reflects the laser light output from the light source 800. The mirror 803 reflects the laser light output from the electro-optical device 801.

The optical system 804 is an imaging optical system, and may be, for example, a bi-telecentric optical system in which a reflection surface of the electro-optical device 801 and an entrance pupil plane of the condensing unit 805 have an imaging relationship.

The condensing unit 805 condenses laser light and irradiates a surface of an object to be processed Ob with the laser light.

For example, the support unit 806 adsorbs the object to be processed Ob to support the object to be processed Ob such that an upper surface of the object to be processed Ob becomes parallel to a horizontal plane. For example, the support unit 806 may be configured to be translationally movable and rotatable in the horizontal plane.

Operation of the laser processing device 108 will be described hereinafter.

Laser light emitted from the light source 800 is reflected by the mirror 802 and enters the electro-optical device 801. In the electro-optical device 801, light that has been appropriately phase-modulated by a phase modulation element in the pixel circuit provided as a reflective pixel in the electro-optical device 801 is emitted to the mirror 803 as reflected light. At this time, the laser light is phase-modulated and emitted without a polarization plane of the electro-optical device 801 being modified.

The phase-modulated laser light output from the electro-optical device 801 is reflected by the mirror 803 to the optical system 804. As described above, since the optical system 804 forms the telecentric optical system in which the reflection surface of the electro-optical device 801 and the entrance pupil plane of the condensing unit 805 have an imaging relationship, the laser light output from the electro-optical device 801 forms an image on the entrance pupil plane of the condensing unit 805.

The condensing unit 805 condenses and radiates the laser light on a planar surface of the object to be processed Ob disposed at an appropriate position by the support unit 806, and projects an image formed on an incident surface onto a surface of the object to be processed Ob at a predetermined magnification. As a result, a modified region of a pattern of the projected image is formed on the surface of the object to be processed Ob.

In the present application example, an image forming a pattern to be formed in the modified region is formed by the electro-optical device 801. The electro-optical device 801 can suppress an increase in size as described in each of the above-described embodiments. Therefore, it is also possible to suppress an increase in size of the laser processing device 108 including the electro-optical device 801 described above.

### Second Application Example

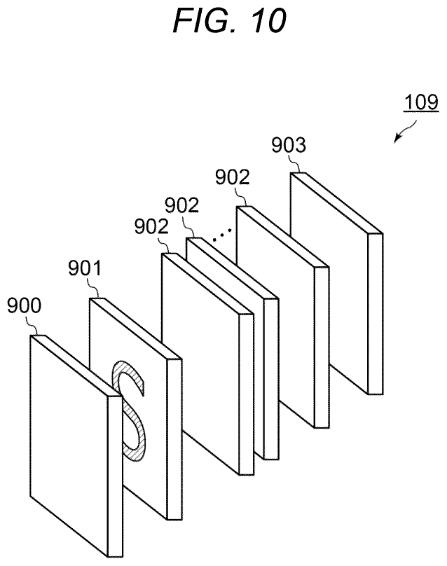

FIG. 10 is a diagram illustrating an example in which the electro-optical device is applied to an optical computing device 109. The optical computing device 109 includes a light source 900, a light valve 901, a plurality of electro-optical devices 902, and a detection unit 903.

In the present application example, the electro-optical devices 902 include any one of the pixel circuits described in the first to sixth embodiments, so that a transmissive liquid crystal display device can be obtained. In the optical computing device 109, the electro-optical devices 902 are superimposed upon each other with predetermined spacings.

The light source 900 irradiates the light valve 901 with laser light. The light valve 901 is, for example, a transmissive light modulator, and modulates light intensity of laser light incident from the light source 900 on the basis of a control signal (image data) input from the outside. As a result, the light valve 901 generates image light having a pattern corresponding to the control signal input from the outside.

For example, the light valve 901 irradiates a first electro-optical device 902 facing the light valve 901 with the generated image light. The image light is phase-modulated by the first electro-optical device 902, and resultant light is radiated onto a second electro-optical device 902 facing the first electro-optical device 902. The light radiated onto the second electro-optical device 902 is phase-modulated by the second electro-optical device 902, and resultant light is radiated onto a third electro-optical device 902 facing the second electro-optical device 902.

The image light is thus phase-modulated by each electro-optical device 902, and light output from the last electro-optical device 902 is detected by the detection unit 903. The detection unit 903 estimates image data input to the light valve 901 on the basis of the input light.

Note that, in the present application example, the light source 900 and the light valve 901 may be omitted. In this case, the first electro-optical device 902 may be irradiated with image light input from the outside. In addition, in the present application example, in a case where the light source 900 and the light valve 901 are omitted, a paper surface having optical transparency on which characters are written or pictures are drawn may be disposed on a light incident surface of the first electro-optical device 902, and external light transmitted through the paper surface may be detected by the first electro-optical device 902.

In the present application example, a phase distribution that determines processing content in the optical computing device 109 is formed by the electro-optical device 902. As a result, it is possible to achieve optical computing that can be downsized.

### Third Application Example

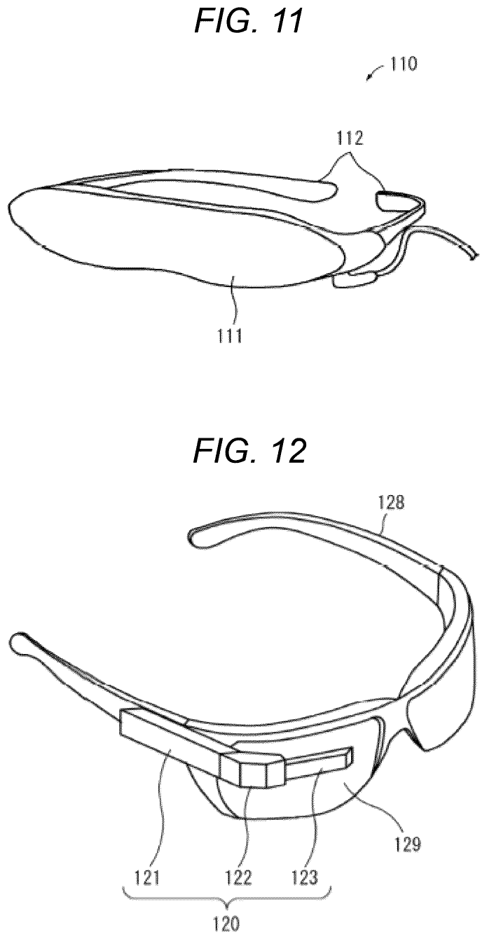

FIG. 11 is a diagram illustrating an example of external appearance of a head mounted display 110. The head mounted display 110 includes, for example, ear hooking portions 112 to be worn on the head of a user on both sides of an eyeglass-shaped display unit 111. The electro-optical device according to each of the above embodiments and the like can be applied to the head mounted display 110.

### Fourth Application Example

FIG. 12 is a diagram illustrating an example of external appearance of another head mounted display 120. The head mounted display 120 is a transmissive head mounted display including a main body portion 121, an arm portion 122, and a lens barrel portion 123. The head mounted display 120 is mounted on glasses 128. The main body portion 121 includes a control board for controlling operation of the head mounted display 120, and a display unit. The display unit emits image light of a display image. The arm portion 122 connects the main body portion 121 and the lens barrel portion 123 and supports the lens barrel portion 123. The lens barrel portion 123 projects image light supplied from the main body portion 121 via the arm portion 122 toward the user's eyes via lenses 129 of the glasses 128. The electro-optical device according to each of the above embodiments and the like can be applied to the head mounted display 120.

Note that the head mounted display 120 is a so-called light guide plate type head mounted display, but is not limited thereto, and may be, for example, a so-called birdbath type head mounted display, instead. The birdbath type head mounted display includes, for example, a beam splitter and a partially transparent mirror. The beam splitter outputs light encoded with image information toward the mirror, and the mirror reflects the light toward the user's eyes. Both the beam splitter and the partially transparent mirror are partially transparent. Light from a surrounding environment thus reaches the user's eyes.

### Fifth Application Example

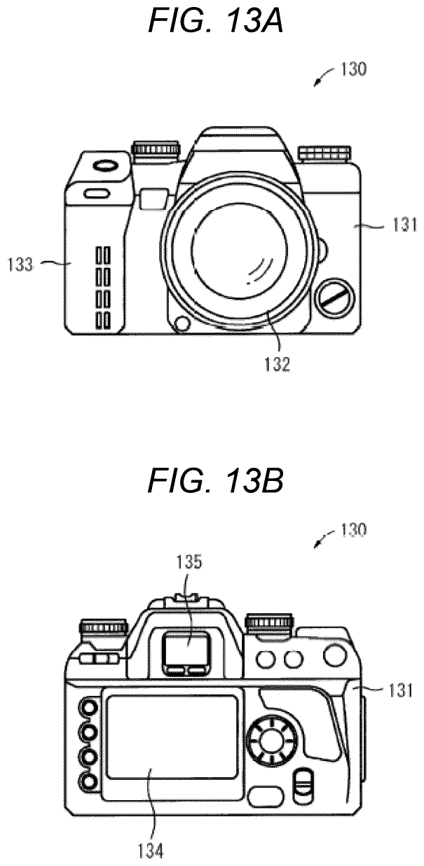

FIGS. 13A and 13B are diagrams illustrating an example of external appearance of a digital still camera 130. FIG. 13A is a front view, and FIG. 13B is a rear view. The digital still camera 130 is a lens interchangeable single-lens reflex type camera, and includes a camera main body portion (camera body) 131, an imaging lens unit 132, a grip portion 133, a monitor 134, and an electronic viewfinder 135. The imaging lens unit 132 is an interchangeable lens unit, and is provided near substantially the center of a front surface of the camera main body portion 131. The grip portion 133 is provided on a left side of the front surface of the camera main body portion 131, and a camera operator grips the grip portion 133. The monitor 134 is provided on a left side of substantially the center of the back surface of the camera main body portion 131. The electronic viewfinder 135 is provided on the upper part of the monitor 134 on the back surface of the camera main body portion 131. By looking into the electronic viewfinder 135, the camera operator can visually recognize an optical image of the subject guided from the imaging lens unit 132 and determine the composition. The electro-optical device according to each of the above embodiments and the like can be applied to the electronic viewfinder 135.

### Sixth Application Example

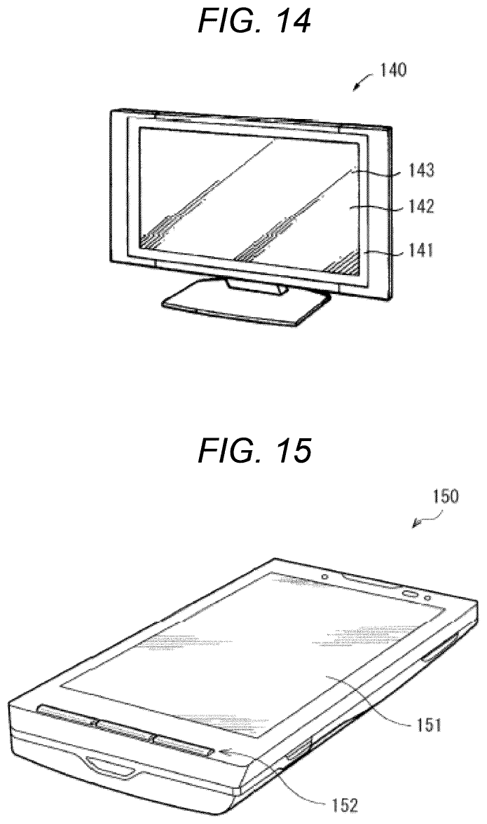

FIG. 14 is a diagram illustrating an example of external appearance of a television apparatus 140. The television apparatus 140 includes a video display screen portion 141 including a front panel 142 and a filter glass 143. The electro-optical device according to each of the above embodiments and the like can be applied to the video display screen portion 141.

### Seventh Application Example

FIG. 15 is a diagram illustrating an example of external appearance of a smartphone 150. The smartphone 150 includes a display unit 151 that displays various types of information and an operation unit 152 including a button that receives an operation input by the user and the like. The electro-optical device according to each of the above embodiments and the like can be applied to the display unit 151.

### Eighth Application Example

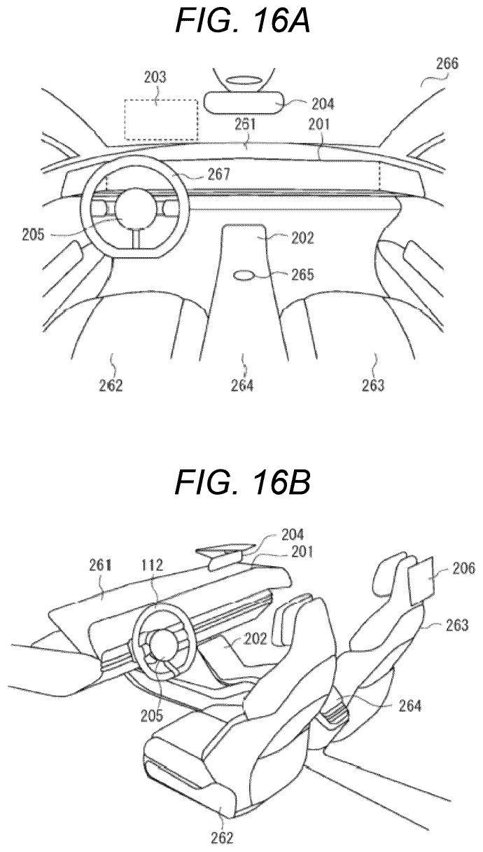

FIGS. 16A and 16B are diagrams illustrating a configuration example of a vehicle to which the electro-optical device of the present disclosure is applied. FIG. 16A illustrates an example of an inside of a vehicle 200 as viewed from a rear portion of the vehicle, and FIG. 16B illustrates an example of the inside of the vehicle 200 as viewed from the left rear of the vehicle.

The vehicle in FIGS. 16A and 16B includes a center display 201, a console display 202, a head-up display 203, a digital rear mirror 204, a steering wheel display 205, and a rear entertainment display 206.

The center display 201 is disposed on a dashboard 261 at a position facing a driver's seat 262 and a passenger seat 263. FIG. 16A illustrates an example of the center display 201 having a horizontally long shape extending from a driver's seat 262 side to a passenger seat 263 side, but screen size and an arrangement location of the center display 201 are not limited thereto. The center display 201 can display information detected by various sensors. As a specific example, the center display 201 can display a captured image captured by the image sensor, a distance image to an obstacle in front of or on a side of the vehicle measured by the ToF sensor, a body temperature of the occupant detected by the infrared sensor, and the like. The center display 201 can be used to display at least one piece of safety-related information, operation-related information, life logs, health-related information, authentication/identification-related information, or entertainment-related information, for example.

The safety-related information is information such as doze detection, looking-away detection, mischief detection of a child riding together, presence or absence of wearing a seat belt, and detection of leaving of an occupant based on a detection result of the sensor. The operation-related information is gesture information regarding the operation of the occupant detected using the sensor. The gesture may include operations of various facilities in the vehicle, for example, operations of an air conditioning equipment, a navigation device, an Audio Visual (AV) device, a lighting device, and the like. The life logs include life logs of all the occupants. For example, the life log includes an action record of each occupant. By acquiring and storing the life log, it is possible to confirm the state of the occupant when the accident occurs. The health-related information includes the body temperature of the occupant detected using the temperature sensor and information on the health condition of the occupant estimated on the basis of the detected body temperature. Alternatively, the information on the health condition of the occupant may be estimated on the basis of the face of the occupant captured by the image sensor. Furthermore, the information on the health condition of the occupant may be estimated on the basis of an answer content of the occupant obtained by talking with the occupant using the automatic voice. The authentication/identification-related information includes information such as a keyless entry function for performing face authentication using a sensor and an automatic adjustment function of a seat height and a position in face identification. The entertainment-related information includes operation information of the AV device by the occupant detected by the sensor, information of content suitable for the occupant detected and recognized by the sensor, and the like.

The console display 202 can be used to display the life log information, for example. The console display 202 is disposed near a shift lever 265 in a center console 264 between the driver's seat 262 and the passenger seat 263. The console display 202 can also display information detected by various sensors. Furthermore, the console display 202 may display an image of the periphery of the vehicle captured by the image sensor, or may display a distance image to an obstacle in the periphery of the vehicle.

The head-up display 203 is virtually displayed behind a windshield 266 in front of the driver's seat 262. The head-up display 203 can be used to display at least one piece of information including the safety-related information, the operation-related information, the life logs, the health-related information, the authentication/identification-related information, and the entertainment-related information, for example. Because the head-up display 203 is often virtually disposed in front of the driver's seat 262, the head-up display 203 is suitable for displaying information directly related to the operation of the vehicle, such as the speed of the vehicle, the remaining amount of fuel, and the remaining amount of the battery.

The digital rear mirror 204 can display not only the rear of the vehicle but also the state of the occupant in the rear seat, and thus can be used to display the life log information of the occupant in the rear seat, for example.

The steering wheel display 205 is disposed near the center of a steering wheel 267 of the vehicle. The steering wheel display 205 can be used to display at least one piece of information including the safety-related information, the operation-related information, the life logs, the health-related information, the authentication/identification-related information, and the entertainment-related information, for example. In particular, because the steering wheel display 205 is close to the hands of the driver, the steering wheel display 205 is suitable for displaying life log information such as the body temperature of the driver, or for displaying information regarding the operation of the AV device, air conditioning equipment, or the like.

The rear entertainment display 206 is attached to the back side of the driver's seat 262 and the passenger seat 263, and is for viewing by an occupant in the rear seat. The rear entertainment display 206 can be used to display at least one piece of information including the safety-related information, the operation-related information, the life logs, the health-related information, the authentication/identification-related information, and the entertainment-related information, for example. In particular, because the rear entertainment display 206 is in front of the occupant in the rear seat, information related to the occupant in the rear seat is displayed. The rear entertainment display 206 may display, for example, information regarding the operation of an AV device or air conditioning equipment, or may display a result of measuring a body temperature or the like of the occupant in the rear seat by a temperature sensor 5.

The electro-optical device according to each of the above embodiments and the like can be applied to the center display 201, the console display 202, the head-up display 203, the digital rear mirror 204, the steering wheel display 205, and the rear entertainment display 206.

### Ninth Application Example

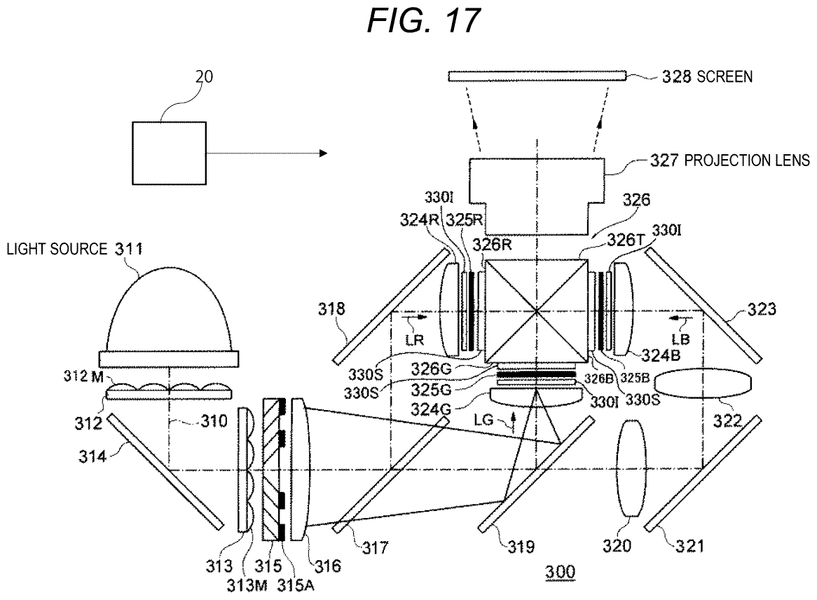

FIG. 17 is a diagram illustrating an optical configuration example of a liquid crystal projector. A liquid crystal projector 300 illustrated in FIG. 17 includes a light source 311 that emits light, a first lens array 312 disposed on an emission side of the light from the light source 311, a mirror 314 that reflects the light emitted from the first lens array 312 and that changes an optical path (optical axis 310) of the emitted light by 90°, and a second lens array 313 on which the light reflected from the mirror 314 is incident. The mirror 314 is preferably a total reflection mirror.

A plurality of microlenses 312M and 313M is two-dimensionally arranged in the first lens array 312 and the second lens array 313, respectively. The first lens array 312 and the second lens array 313 are used to make illuminance distribution of light uniform, and have a function of dividing incident light into a plurality of small light fluxes.

Note that an Ultra Violet (UV)/Infrared (IR) cut filter (not illustrated) may be installed between the light source 311 and the first lens array 312.

The light source 311 emits white light including red light, blue light, and green light required for color image display. The light source 311 includes a light emitter (not illustrated) that emits white light, and a reflector that reflects and collects the light emitted from the light emitter.

As the light emitter, for example, a lamp such as an ultra-high pressure mercury lamp, a halogen lamp, a metal halide lamp, or a xenon lamp is used. The reflector desirably has a shape with good light collection efficiency, and has a rotationally symmetric concave surface shape such as a rotational ellipsoidal mirror or a rotational parabolic mirror. In addition, a light emission point of the light emitter is disposed at a focal position of the concave reflector.

The white light emitted from the light emitter of the light source 311 becomes substantially parallel light due to the reflector, passes through the first lens array 312, and enters the mirror 314. The white light whose optical axis 310 is bent by 90° by the mirror 314 is incident on the second lens array 313.

The liquid crystal projector 300 illustrated in FIG. 17 includes a PS synthesis element 315, a condenser lens 316, and a dichroic mirror 317 on an emission side of light from the second lens array 313.

The PS synthesis element 315 is provided with a plurality of retardation plates 315A at positions corresponding to between adjacent microlenses in the second lens array 313. 1/2 wave plates are an example of the retardation plates 315A.

The PS synthesis element 315 separates the incident light into polarized light of a P-polarized component and an S-polarized component. Furthermore, the PS synthesis element 315 emits one of the two components of the separated polarized light from a polarization conversion element while maintaining a polarization direction (for example, the P-polarized light), and converts the other component of the polarized light (for example, the S-polarized component) into another polarized component (for example, the P-polarized component) by the action of the ½ wave plates 315A and emits the other polarized component.

The light emitted from the PS synthesis element 315 is condensed by the condenser lens 316 and enters the dichroic mirror 317.

The dichroic mirror 317 reflects, for example, red light LR in the incident light and transmits light of other colors, thereby color-separating the incident light into the red light LR and the other colors.

Furthermore, the liquid crystal projector 300 includes a mirror 318, a field lens 324R, an incident side polarizing plate 330I, a liquid crystal panel 325R, and an emission side polarizing plate 330S along an optical path of the red light LR color-separated by the dichroic mirror 317.

As the mirror 318, a total reflection mirror is preferably used. The mirror 318 reflects the red light LR color-separated by the dichroic mirror 317 toward the incident side polarizing plate 330I and the liquid crystal panel 325R.

As described above, the incident side polarizing plate 330I allows light in a direction coinciding with a polarization axis 330a in the red light LR incident from the mirror 318 to pass therethrough.

The liquid crystal panel 325R spatially modulates the red light LR incident through the incident side polarizing plate 330I according to input image data. In the modulated red light LR from the liquid crystal panel 325R, the emission side polarizing plate 330S allows light in a direction coinciding with a polarization axis 330b to pass therethrough.

The liquid crystal projector 300 includes a dichroic mirror 319 along an optical path of the light of the other colors separated by the dichroic mirror 317. The dichroic mirror 319 reflects, for example, green light LG and transmits blue light LB in the incident light, thereby color-separating the incident light into the green light LG and the blue light LB.

A field lens 324G, an incident side polarizing plate 330I, a liquid crystal panel 325G, and an emission side polarizing plate 330S are provided along an optical path of the green light LG color-separated by the dichroic mirror 319.

The incident side polarizing plate 330I allows light in a direction coinciding with the polarization axis 330a in the green light LG incident from the dichroic mirror 319 to pass therethrough.

The liquid crystal panel 325G spatially modulates the green light LG incident through the incident side polarizing plate 330I according to input image data.

In the modulated green light LG from the liquid crystal panel 325G, the emission side polarizing plate 330S allows light in a direction coinciding with the polarization axis 330b to pass therethrough.

Furthermore, a relay lens 320, a mirror 321, a relay lens 322, a mirror 323, a field lens 324B, an incident side polarizing plate 330I, a liquid crystal panel 325B, and an emission side polarizing plate 330S are provided along an optical path of the blue light LB color-separated by the dichroic mirror 319.

The mirrors 321 and 323 are preferably total reflection mirrors. The mirror 321 reflects the blue light LB incident through the relay lens 320 toward the mirror 323. The mirror 323 reflects the blue light LB reflected by the mirror 321 and incident through the relay lens 322 toward the incident side polarizing plate 330I and the liquid crystal panel 325B.

The incident side polarizing plate 330I allows light in a direction coinciding with a polarization axis 330a in the green light LG incident from the mirror 323 to pass therethrough.

The liquid crystal panel 325B spatially modulates the blue light LB reflected by the mirror 323 and incident through the field lens 324B and the incident side polarizing plate 330I according to input image data.

In the modulated blue light LB from the liquid crystal panel 325B, the emission side polarizing plate 330S allows light in a direction coinciding with the polarization axis 330b to pass therethrough. A cross prism 326 having a function of combining these three beams of color light is installed at a position where the optical paths of the red light LR, the green light LG, and the blue light LB intersect.

As an example, the cross prism 326 is formed by joining four right angle prisms having incident surfaces 326R, 326G, and 326B on which the red light LR, the green light LG, and the blue light LB are incident, and an emission surface 326T from which light obtained by combining the red light LR, the green light LG, and the blue light LB is emitted, respectively.

In the liquid crystal projector 300, a dichroic film is coated on a joint surface of each right angle prism such that the green light LG incident on the cross prism 326 is transmitted toward an emission surface 326T side, and the red light LR and the blue light LB incident on the cross prism 326 are reflected toward the emission surface 326T side.

The cross prism 326 thus combines the three beams of color light incident on the incident surfaces 326R, 326G, and 326B and emits the combined light from the emission surface 326T.

In addition, the liquid crystal projector 300 also includes a projection lens 327 for projecting the combined light emitted from cross prism 326 toward a screen 328. The projection lens 327 preferably includes a plurality of lenses, and has a zoom function for adjusting a size of an image to be projected on the screen 328 and a focus function.

Note that the above-described effects can be obtained even when the present disclosure is applied to not only the projection type liquid crystal display element but also any type of device such as a reflection type liquid crystal display element or an LCOS.

In addition, the above-described effects can be expected even when the present disclosure is applied to any type of liquid crystal display element such as a liquid crystal display element with a built-in drive, a liquid crystal display element with a drive circuit externally attached thereto, a liquid crystal display element with various sizes of a diagonal of about 1 inch to 15 inches or more, a simple matrix type, a TFD active matrix type, a passive matrix drive type, a polarization-rotation mode, and a birefringence mode.

In the present application example, the electro-optical device according to the above embodiment and the like can be applied to each of the liquid crystal panels 325R, 325G, and 325B.

Note that the present technology may have the following configurations.

(1) An electro-optical device including:
a liquid crystal element driven on the basis of a data signal indicating a degree of light modulation;
a plurality of electronic components related to the driving of the liquid crystal element based on the data signal;
a first semiconductor layer in which the liquid crystal element and a subset of the plurality of electronic components are disposed; and
a second semiconductor layer that is stacked on the first semiconductor layer and in which remaining components of the plurality of electronic components are disposed.

(2) The electro-optical device according to (1), in which the first semiconductor layer is an oxide semiconductor layer, and
the second semiconductor layer is a silicon semiconductor layer.

(3) The electro-optical device according to (1) or (2), in which the plurality of electronic components includes:
a sampling transistor that samples the data signal;
a buffer circuit that amplifies the data signal sampled by the sampling transistor; and
a transfer transistor that transfers the data signal amplified by the buffer circuit to the liquid crystal element. (4) The electro-optical device according to (3), in which the buffer circuit is disposed in the first semiconductor layer, and
the sampling transistor and the transfer transistor are disposed in the second semiconductor layer.

(5) The electro-optical device according to (4), in which the sampling transistor and the transfer transistor are CMOS transistors.

(6) The electro-optical device according to (3), in which the buffer circuit and the transfer transistor are disposed in the first semiconductor layer, and
the sampling transistor is disposed in the second semiconductor layer.

(7) The electro-optical device according to (6), in which the sampling transistor is a CMOS transistor.

(8) The electro-optical device according to (3), in which the sampling transistor and the transfer transistor are disposed in the first semiconductor layer, and
the buffer circuit is disposed in the second semiconductor layer.

(9) The electro-optical device according to (8), in which the buffer circuit is a source follower circuit.

(10) The electro-optical device according to (8), in which the buffer circuit is a voltage follower circuit.

(11) The electro-optical device according to (1) or (2), in which the plurality of electronic components includes two sampling transistors that sample the data signal and two transfer transistors that transfer the data signal sampled by the sampling transistors to the liquid crystal element,
the two transfer transistors are disposed in the first semiconductor layer, and
the two sampling transistors are disposed in the second semiconductor layer.

(12) The electro-optical device according to (11), in which the two sampling transistors are CMOS transistors.

(13) The electro-optical device according to (1) or (2), in which the plurality of electronic components includes a signal generation circuit that generates the data signal, a buffer circuit that amplifies the data signal generated by the signal generation circuit, and a transfer transistor that transfers the data signal amplified by the buffer circuit to the liquid crystal element,
a part of the signal generation circuit, the buffer circuit, and the transfer transistor are disposed in the first semiconductor layer, and
a remaining part of the signal generation circuit is disposed in the second semiconductor layer.

(14) The electro-optical device according to (13), in which the signal generation circuit includes a comparison circuit that compares a digital signal indicating a gradation value of the liquid crystal element with a reference signal, an AND circuit that performs an AND operation on a result of the comparison by the comparison circuit, a level shift circuit that shifts a level of a voltage of a digital signal indicating a result of the operation by the AND circuit, and a DAC transistor that performs analog conversion on the digital signal and that outputs the data signal,
the DAC transistor is disposed in the first semiconductor layer, and
the comparison circuit, the AND circuit, and the level shift circuit are disposed in the second semiconductor layer.

(15) A spatial light modulator including an electro-optical device, in which the electro-optical device includes:
a liquid crystal element driven on the basis of a data signal indicating a degree of light modulation;
a plurality of electronic components related to the driving of the liquid crystal element based on the data signal;
a first semiconductor layer in which the liquid crystal element and a subset of the plurality of electronic components are disposed; and
a second semiconductor layer that is stacked on the first semiconductor layer and in which remaining components of the plurality of electronic components are disposed.

Aspects of the present disclosure are not limited to the embodiment described above, but include various conceivable modifications, and the effects of the present disclosure are also not limited to the contents described above. The components in each embodiment may be appropriately combined and applied. In other words, various additions, modifications, and partial deletions may be made without departing from the conceptual idea and spirit of the present disclosure derived from the matters defined in the claims and equivalents thereof.

### REFERENCE SIGNS LIST

1 Electro-optical device
10 Pixel array
30 Buffer circuit
50 Signal generation circuit
51 Comparison circuit
52 AND circuit
53 Level shift circuit
100 Pixel circuit
101 Pixel circuit
102 Pixel circuit
103 Pixel circuit
104 Pixel circuit
105 Pixel circuit
106 Pixel circuit
301 First semiconductor layer
302 Second semiconductor layer
801 Electro-optical device
902 Electro-optical device

1. An electro-optical device comprising:
a liquid crystal element driven on a basis of a data signal indicating a degree of light modulation;
a plurality of electronic components related to the driving of the liquid crystal element based on the data signal;
a first semiconductor layer in which the liquid crystal element and a subset of the plurality of electronic components are disposed; and
a second semiconductor layer that is stacked o the first semiconductor layer and in which remaining components of the plurality of electronic components are disposed.

2. The electro-optical device according to claim 1, wherein the first semi-conductor layer is an oxide semiconductor layer, and
the second semiconductor layer is a silicon semiconductor layer.

3. The electro-optical device according to claim 2, wherein the plurality of electronic components includes:
a sampling transistor that samples the data signal;
a buffer circuit that amplifies the data signal sampled by the sampling transistor; and
a transfer transistor that transfer the data signal amplified by the buffer circuit to the liquid crystal element.

4. the electro-optical device according to claim 3, wherein the buffer circuit is disposed in the first semiconductor layer, and
the sampling transistor and the transfer transistor are disposed in the second semiconductor layer.

5. The electro-optical device according to claim 4, wherein the sampling transistor and the transfer transistor are CMOS transistors.

6. The electro-optical device according to claim 3, wherein the buffer circuit and the transfer transistor are disposed in the first semiconductor layer, and
the sampling transistor is disposed in the second semiconductor layer.

7. The electro-optical device according to claim 6, wherein the sampling transistor is a CMOS transistor.

8. The electro-optical device according to claim 3, wherein the sampling transistor and the transfer transistor are disposed in the first semiconductor layer, and
the buffer circuit is disposed in the second semiconductor layer.

9. The electro-optical device according to claim 8, wherein the buffer circuit is a source follower circuit.

10. The electro-optical device according to claim 8, wherein the buffer circuit is a voltage follower circuit.

11. The electro-optical device according to claim 2, wherein the plurality of electronic components includes two sampling transistors that sample the data signal and two transfer transistors that transfer the data signal sampled by the sampling transistors to the liquid crystal element,
the two transfer transistors are disposed in the first semiconductor layer, and
the two sampling transistors are disposed in the second semiconductor layer.

12. The electro-optical device according to claim 11, wherein the two sampling transistors are CMOS transistors.

13. The electro-optical device according to claim 2, wherein the plurality of electronic components includes a signal generation circuit that generates the data signal, a buffer circuit that amplifies the data signal generated by the signal generation circuit, and a transfer transistor that transfers the data signal amplified by the buffer circuit to the liquid crystal element,
a part of the signal generation circuit, the buffer circuit, and the transfer transistor are disposed in the first semiconductor layer, and
a remaining part of the signal generation circuit is disposed in the second semiconductor layer.

14. The electro-optical device according to claim 13, wherein the signal generation circuit includes a comparison circuit that compares a digital signal indicating a gradation value of the liquid crystal element with a reference signal, an AND circuit that performs an AND operation on a result of the comparison by the comparison circuit, a level shift circuit that shifts a level of a voltage of a digital signal indicating a result of the operation by the AND circuit, and a DAC transistor that performs analog conversion on the digital signal and that outputs the data signal,
the DAC transistor is disposed in the first semiconductor layer, and
the comparison circuit, the AND circuit, and the level shift circuit are disposed in the second semiconductor layer.

15. A spatial light modulator comprising an electro-optical device, wherein the electro-optical device includes:
a liquid crystal element driven on a basis of a data signal indicating a degree of light modulation;
a plurality of electronic components related to the driving of the liquid crystal element based on the data signal;
a first semiconductor layer in which the liquid crystal element and a subset of the plurality of electronic components are disposed; and
a second semiconductor layer that is stacked on the first semiconductor layer and in which remaining components of the plurality of electronic components are disposed.
